(19) United States
(12) Patent Application Publication
(10) Pub. No.: US 2025/0069999 A1
(43) Pub. Date: Feb. 27, 2025

(54) DYNAMIC PLATED METAL THICKNESS FOR SEMICONDUCTOR PACKAGE

(71) Applicant: Texas Instruments Incorporated, Dallas, TX (US)

(72) Inventors: Huo Yun Duan, Chengdu (CN); Qin Peng, Chengdu (CN); Tian Sheng Chen, Chengdu (CN); Xiangrui Li, Chengdu (CN); Hang Yan, Chengdu (CN)

(21) Appl. No.: 18/454,242

(22) Filed: Aug. 23, 2023

(51) Int. Cl. H01L 23/495; C25D 3/12; C25D 3/30; C25D 3/46; C25D 3/48; C25D 3/50; C25D 7/12; H01L 21/48; H01L 23/31

(52) U.S. Cl. CPC H01L 23/49582; C25D 3/12; C25D 3/30; C25D 3/46; C25D 3/48; C25D 3/50; C25D 7/12; H01L 21/4821; H01L 23/3107; H01L 23/49555; H01L 24/32; H01L 24/48; H01L 24/73; H01L 2224/32245; H01L 2224/48245; H01L 2224/73265

(57) ABSTRACT

A semiconductor package includes a semiconductor component and a plurality of leads electrically connected to the semiconductor component. Each of the leads has a first surface, and has a second surface opposite from the first surface, with a solderable metal on the first surface and the second surface. The solderable metal has a first average thickness on the first surfaces, and has a second average thickness on the second surfaces. The second average thickness is 10 percent to 80 percent of the first average thickness. The semiconductor package is formed by concurrently electroplating the solderable metal on the first surfaces and on the second surfaces. The solderable metal is electroplated on the first surfaces with a first average current, and is electroplated on the second surfaces with a second average current. The second average current is 10 percent to 80 percent of the first average current.

### TECHNICAL FIELD

This disclosure relates to the field of semiconductor packages. More particularly, but not exclusively, this disclosure relates to plated lead frames in semiconductor packages.

### BACKGROUND

An important aspect of semiconductor packaging is integration of lead frames that serve as a bridge between internal semiconductor components and the external world, enabling the transfer of electrical signals and power. Lead frames are commonly manufactured using various methods, including stamping and etching processes of metal sheets or strips that form the foundation of the lead frames. The patterned metal sheets or strips, commonly made of materials like copper and copper alloys, are then bent and shaped to accommodate the specific requirements of the semiconductor package. However, the increasing demand for higher performance and miniaturization of semiconductor packages, coupled with the need for enhanced soldering reliability, has driven the development of novel techniques and materials for constructing lead frames. Electroplating is commonly used for producing lead frames with improved performance characteristics, particularly when it comes to soldering reliability. The quality of the solder joints is important for ensuring reliable electrical connections and long-term device functionality. Electroplated lead frames provide a means to address these requirements.

### SUMMARY

The present disclosure introduces a semiconductor package including a semiconductor component and a plurality of leads electrically connected to the semiconductor component. The leads extend through an encapsulation material to an exterior of the semiconductor package. Each of the leads has a first surface, and has a second surface opposite from the first surface, with a solderable metal on the first surface and the second surface. A portion of the first surface provides an area for a solder joint to a system substrate, such as a printed circuit board, when the semiconductor package is assembled into an electronic apparatus. The solderable metal has a first average thickness on the first surfaces, and has a second average thickness on the second surfaces. The second average thickness is 10 percent to 80 percent of the first average thickness. The semiconductor package is formed by concurrently electroplating the solderable metal on the first surfaces and on the second surfaces. The solderable metal is electroplated on the first surfaces with a first average current, and is electroplated on the second surfaces with a second average current. The second average current is 10 percent to 80 percent of the first average current.

### BRIEF DESCRIPTION OF THE VIEWS OF THE DRAWINGS

FIG. 1 is a cross section of an example semiconductor package having a second average thickness of a solderable metal on second surfaces of leads that is less than a first average thickness of the solderable metal on first surfaces of the leads.

FIG. 2 is a cross section of another example semiconductor package having a second average thickness of a solderable metal on second surfaces of leads that is less than a first average thickness of the solderable metal on first surfaces of the leads.

FIG. 3A and FIG. 3B depict an example method of forming a semiconductor package having a second average thickness of a solderable metal on second surfaces of leads that is less than a first average thickness of the solderable metal on first surfaces of the leads.

FIG. 4A and FIG. 4B depict another example method of forming a semiconductor package having a second average thickness of a solderable metal on second surfaces of leads that is less than a first average thickness of the solderable metal on first surfaces of the leads.

FIG. 5 depicts a further example method of forming a semiconductor package having a second average thickness of a solderable metal on second surfaces of leads that is less than a first average thickness of the solderable metal on first surfaces of the leads.

FIG. 6 is a chart of current as a function of time for the plating system disclosed in reference to FIG. 5.

FIG. 7 depicts another example method of forming a semiconductor package having a second average thickness of a solderable metal on second surfaces of leads that is less than a first average thickness of the solderable metal on first surfaces of the leads.

FIG. 8 is a chart of current as a function of time for the plating system disclosed in reference to FIG. 7.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

A semiconductor package includes a semiconductor component. The semiconductor package also includes leads of a lead frame. The semiconductor component is electrically connected to one or more of the leads. The leads each have a first surface and a second surface opposite from the first surface. A solderable metal, such as primarily tin, silver, nickel, gold, or palladium, or an alloy thereof, is electroplated on the first surface and the second surface. The solderable metal has a first average thickness on the first surfaces, and has a second average thickness on the second surfaces. The first and second average thicknesses are the thicknesses of the solderable metal in a direction perpendicular to an instant segment of the first and second surfaces of the leads, averaged over an area of the first and second surfaces, respectively. The second average thickness is 10 percent to 80 percent of the first average thickness. When the semiconductor package is assembled into an electronic apparatus by soldering the leads to a system substrate, such as a printed circuit board, a portion of the first surface provides an area for a solder joint. The first average thickness is sufficient to provide reliable solder joints, and may be 5 microns to 20 microns, by way of example. The second average thickness is sufficiently thick, that is, at least 10 percent of the first average thickness, to reduce oxidation or corrosion of the leads, thereby improving reliability of the semiconductor package. The second average thickness is sufficiently thin, that is, no more than 80 percent of the first average thickness, to attain a desired reduction in material costs of the solderable metal. A further advantage may be realized when forming two-dimensional barcodes on the second surface of lead frame before the solderable metal is electroplated. The barcodes may be formed in accordance with SEMI T9 specification and have an array of 100 micron diameter bumps that are on a 100 micron pitch. The thinner solderable metal on the barcodes may improve readability of the barcodes compared to barcodes having the thicker solderable metal. The semiconductor component has an encapsulation material contacting the semiconductor component and the leads. The leads extend through the encapsulation material to an exterior of the semiconductor package.

The semiconductor package is formed by concurrently electroplating the solderable metal on the first surfaces and on the second surfaces. The solderable metal is electroplated on the first surfaces with a first plating current, which may be direct current (DC). The solderable metal is electroplated on the second surfaces with a second plating current, which may be DC or modulated DC, that is, cyclically switched on and off, or cyclically switched between a first DC level and a second DC level. An average current of the second plating current is 10 percent to 80 percent of an average current of the first plating current, to attain a desired thickness ratio of the solderable metal on the first surfaces and on the second surfaces. Electroplating the solderable metal concurrently on the first surfaces and on the second surfaces may advantageously reduce cycle time, and thus reduce fabrication cost, compared to plating the solderable metal on the first surfaces and on the second surfaces in separate sequential operations. For the purposes of this disclosure, the term “concurrently electroplating” includes modulated DC or any other method of providing the first plating current and the second plating current in which the first plating current and the second plating current are flowing simultaneously during at least a portion of an electroplating process used to form the solderable metal on the leads.

For the purposes of this disclosure, a structure that is disclosed as including “primarily” a substance has more than 50 percent, by weight, of that substance. For example, a solderable metal that is disclosed to include primarily tin has more than 50 percent, by weight, of the element tin.

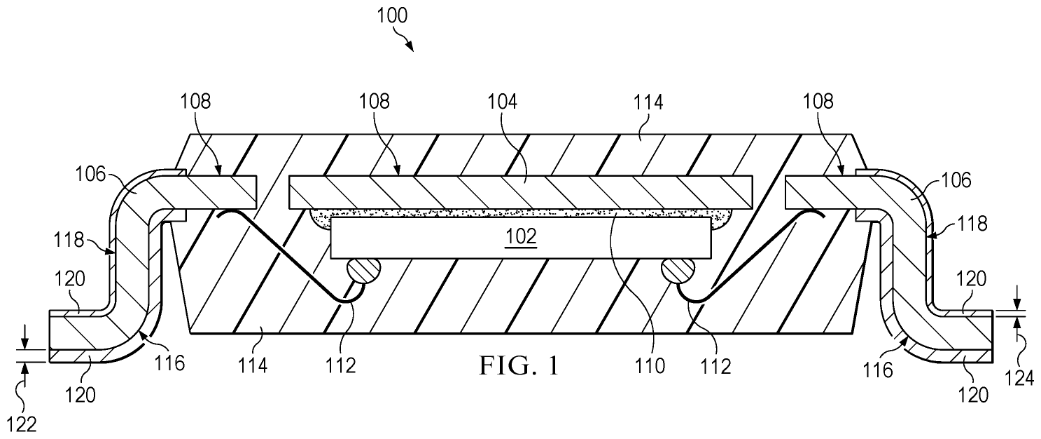

FIG. 1 is a cross section of an example semiconductor package having a second average thickness of a solderable metal on second surfaces of leads that is less than a first average thickness of the solderable metal on first surfaces of the leads. The semiconductor package 100 includes a semiconductor component 102. The semiconductor component 102 may be manifested as an integrated circuit, a discrete semiconductor device, a microelectrical mechanical system (MEMS) device, an electro-optical device, or a microfluidic device, by way of example. The semiconductor package 100 of this example includes a die pad 104, which is part of a lead frame 108. The semiconductor component 102 is attached to the die pad 104, by a die attach material 110, such as solder, an electrically conductive adhesive, or an electrically insulating adhesive. The semiconductor package 100 also includes leads 106, which are parts of the lead frame 108. The semiconductor component 102 is electrically connected to the leads 106 through electrical connections 112. In this example, the electrical connections 112 may be manifested as wire bonds 112, as depicted in FIG. 1.

The semiconductor package 100 includes an encapsulation material 114 contacting the semiconductor component 102 and the leads 106. The encapsulation material 114 may surround the semiconductor component 102, the electrical connections 112, and the die pad 104, as depicted in FIG. 1. The encapsulation material 114 may include epoxy or other polymer material. The encapsulation material 114 may include filler material such as silicon dioxide particles, to reduce a thermal expansion coefficient of the encapsulation material 114. The leads 106 extend through the encapsulation material 114 to an exterior of the semiconductor package 100. In this example, the leads 106 may have a “gull wing” configuration, as depicted in FIG. 1, and the semiconductor package 100 may have a small outline integrated circuit (SOIC) configuration or a small outline transistor (SOT) configuration.

The leads 106 have first surfaces 116 at the exterior of the semiconductor package 100 which will be positioned on a system substrate in an electronic apparatus, not specifically shown, containing the semiconductor package 100. The leads 106 have second surfaces 118 located opposite from the first surfaces 116. The semiconductor package 100 includes a solderable metal 120, such as primarily tin, silver, nickel, gold, or palladium, or an alloy thereof, on the first surfaces 116 and the second surfaces 118 of the leads 106. The solderable metal 120 covers the leads 106 at the exterior of the semiconductor package 100 and, in this example, may extend partway into the encapsulation material 114, as depicted in FIG. 1. The solderable metal 120 may expose a portion of the leads 106 adjacent to the semiconductor component 102 to provide suitable surfaces on the leads 106 for the wire bonds 112. The solderable metal 120 has a first average thickness 122 on the first surfaces 116 and has a second average thickness 124 on the second surfaces 118. The second average thickness 124 is 10 percent to 80 percent of the first average thickness 122, accruing the advantages of reduced cost and reduction of oxidation or corrosion. The first average thickness 122 is sufficient to provide reliable solder joints to the circuit board. The first average thickness 122 may be 5 microns to 20 microns, by way of example.

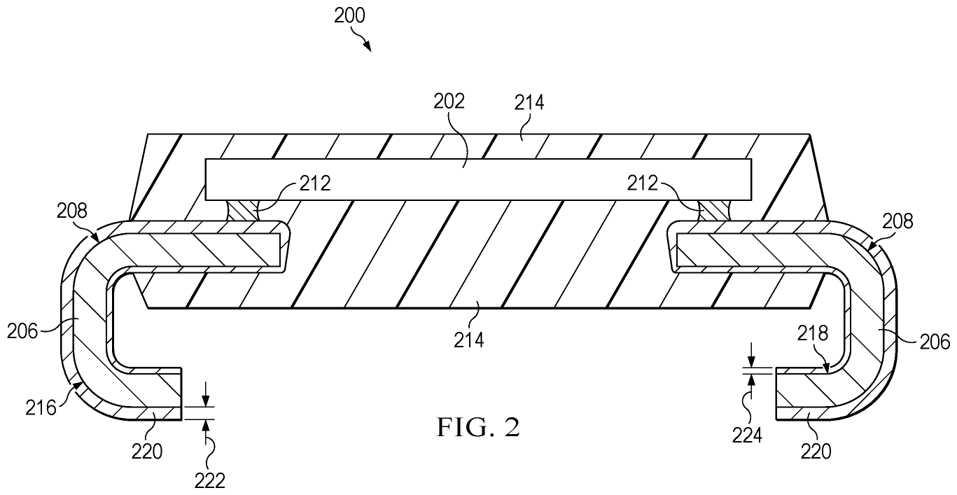

FIG. 2 is a cross section of another example semiconductor package having a second average thickness of a solderable metal on second surfaces of leads that is less than a first average thickness of the solderable metal on first surfaces of the leads. The semiconductor package 200 includes a semiconductor component 202. The semiconductor package 200 includes leads 206, which are parts of a lead frame 208. The semiconductor component 202 is electrically connected to the leads 206 through electrical connections 212, which may be manifested as solder bump bonds 212, as depicted in FIG. 2.

The semiconductor package 200 includes an encapsulation material 214 contacting the semiconductor component 202 and the leads 206. The encapsulation material 214 may surround the semiconductor component 202 and the electrical connections 212, as depicted in FIG. 2. The leads 206 extend through the encapsulation material 214 to an exterior of the semiconductor package 200. In this example, the leads 206 may have a “j-lead” configuration, as depicted in FIG. 2, and the semiconductor package 200 may have a j-lead surface mount technology (SMT) semiconductor package.

The leads 206 have first surfaces 216 at the exterior of the semiconductor package 200, and have second surfaces 218 located opposite from the first surfaces 216. The semiconductor package 200 includes a solderable metal 220 on the first surfaces 216 and the second surfaces 218 of the leads 206. The solderable metal 220 covers the leads 206 at the exterior of the semiconductor package 200 and, in this example, covers the leads 206 in the encapsulation material 214, as depicted in FIG. 2. The solderable metal 220 has a first average thickness 222 on the first surfaces 216 and has a second average thickness 224 on the second surfaces 218. The second average thickness 224 is 10 percent to 80 percent of the first average thickness 222, accruing the advantages of reduced cost and reduction of oxidation or corrosion. The first average thickness 222 may be 5 microns to 20 microns, by way of example.

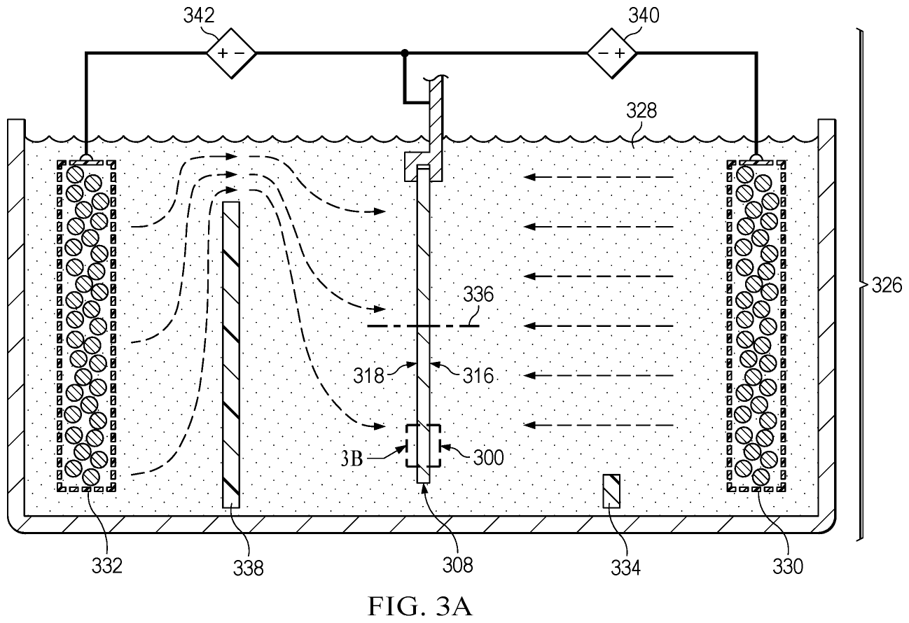

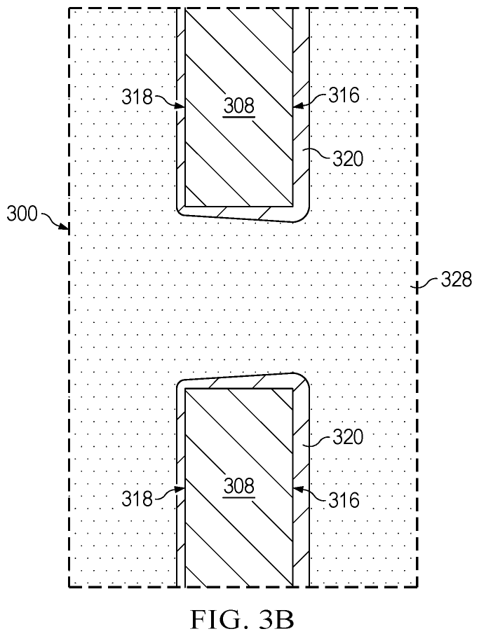

FIG. 3A and FIG. 3B depict an example method of forming a semiconductor package having a second average thickness of a solderable metal on second surfaces of leads that is less than a first average thickness of the solderable metal on first surfaces of the leads. A lead frame 308 for the semiconductor package 300 has first surfaces 316 on one face of the lead frame 308 and has second surfaces 318 on an opposite face from the first surfaces 316. A portion of the lead frame 308 may be masked by tape or a polymer coating, not specifically shown, to prevent electroplating on surfaces for wire bonding.

The lead frame 308 is immersed in a plating system 326. The plating system 326 includes a plating solution 328 having metal ions, such as tin ions, silver ions, nickel ions, gold ions, or palladium ions, of a solderable metal 320, such as tin, silver, nickel, gold, or palladium, or an alloy thereof, respectively, being electroplated onto the lead frame 308. The plating system 326 also includes a first anode 330 facing the first surfaces 316, and includes a second anode 332 facing the second surfaces 318. The first anode 330 and the second anode 332 may be implemented as anode bags containing metal plates or wires of the solderable metal 320. Other implementations of the first anode 330 and the second anode 332 are within the scope of this example.

The plating system 326 may include a first screen 334 positioned between the first surfaces 316 and the first anode 330. The first screen 334 is located so as not to significantly obstruct the metal ions drifting from the first anode 330 to the first surfaces 316. The first screen 334 is located below a center line 336 of the lead frame 308. In one version of this example, the first screen 334 may be located below a bottom of the lead frame 308, as depicted in FIG. 3A.

The plating system 326 includes a second screen 338 positioned between the second surfaces 318 and the second anode 332. The second screen 338 may be solid, that is, may be free of apertures. The second screen 338 is located above the center line 336 of the lead frame 308. In one version of this example, the second screen 338 may extend proximate to a top of the lead frame 308, as depicted in FIG. 3A.

The plating system 326 includes a first power supply 340 configured to supply current from the lead frame 308 to the first anode 330. The first power supply 340 may be implemented as a constant voltage source, as indicated schematically in FIG. 3A. Alternatively, the first power supply 340 may be implemented as a regulated current source.

The plating system 326 includes a second power supply 342 configured to supply current from the lead frame 308 to the second anode 332. The second power supply 342 may be implemented as another constant voltage source. Alternatively, the second power supply 342 may be implemented as a modulated voltage source, a regulated current source, or a modulated current source.

During an electroplating process using the plating system 326, the first power supply 340 causes the metal ions in the plating solution 328 between the first anode 330 and the lead frame 308 to drift to the first surfaces 316 and to electroplate the solderable metal 320 onto the first surfaces 316 of the lead frame 308. In this example, the location of the first screen 334 below the center line 336 of the lead frame 308 enables a relatively unobstructed flow of the metal ions to the first surfaces 316.

The second power supply 342 causes the metal ions in the plating solution 328 between the second anode 332 and the lead frame 308 to drift over the second screen 338 to the second surfaces 318 and to electroplate the solderable metal 320 onto the second surfaces 318. In this example, the location of the second screen 338 above the center line 336 reduces the flow of the metal ions to the second surfaces 318 compared to the unobstructed flow of the metal ions to the first surfaces 316. The first power supply 340 and the second power supply 342 are operated concurrently.

The result is a first average current flowing from the first anode 330 to the first surfaces 316, and a second average current flowing from the second anode 332 to the second surfaces 318. The second average current is 10 percent to 80 percent of the first average current, resulting in the solderable metal 320 being electroplated at a lower rate on the second surfaces 318 compared to the first surfaces 316. The lower electroplating rate on the second surfaces 318 produces a lower thickness of the solderable metal 320 on the second surfaces 318, compared to the first surfaces 316, as disclosed in reference to FIG. 1 and FIG. 2. A height of the second screen 338 may be adjusted to attain a desired thickness of the solderable metal 320 on the second surfaces 318, advantageously enabling use of the second power supply 342 in a constant voltage mode. The first power supply 340 and the second power supply 342 may advantageously be operated at a same constant voltage by proper adjustment of the second screen 338.

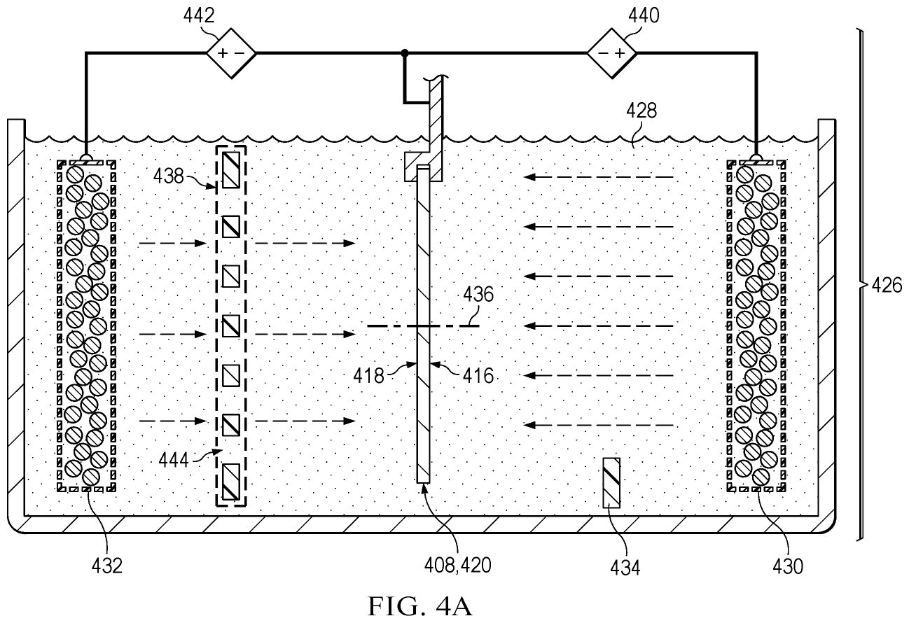

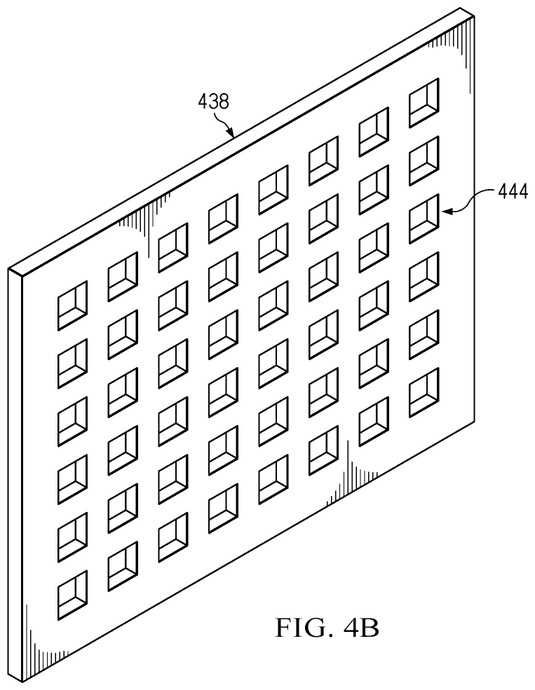

FIG. 4A and FIG. 4B depict another example method of forming a semiconductor package having a second average thickness of a solderable metal on second surfaces of leads that is less than a first average thickness of the solderable metal on first surfaces of the leads. A lead frame 408 for the semiconductor package has first surfaces 416 on one face of the lead frame 408 and has second surfaces 418 on an opposite face from the first surfaces 416. The lead frame 408 is immersed in a plating system 426. The plating system 426 includes a plating solution 428 having metal ions of a solderable metal 420 being electroplated onto the lead frame 408. The plating system 426 also includes a first anode 430 facing the first surfaces 416, and includes a second anode 432 facing the second surfaces 418.

The plating system 426 may include a first screen 434 positioned between the first surfaces 416 and the first anode 430. The first screen 434 is located so as not to significantly obstruct the metal ions drifting from the first anode 430 to the first surfaces 416. The first screen 434 is positioned below a center line 436 of the lead frame 408, for example, below a bottom of the lead frame 408, as depicted in FIG. 4A.

The plating system 426 further includes a second screen 438 positioned between the second surfaces 418 and the second anode 432. In this example, the second screen 438 may be implemented as a perforated screen 438 having apertures 444 to allow reduced flow of the metal ions from the second anode 432 to the second surfaces 418. The second screen 438 is located above the center line 436 of the lead frame 408, and may extend proximate to a top of the lead frame 408, as depicted in FIG. 4A.

The plating system 426 includes a first power supply 440 configured to supply current from the lead frame 408 to the first anode 430, and a second power supply 442 configured to supply current from the lead frame 408 to the second anode 432. The first power supply 440 and the second power supply 442 may be implemented as constant voltage sources, as indicated schematically in FIG. 4A, or may be implemented as regulated current sources.

During an electroplating process using the plating system 426, the first power supply 440 and the second power supply 442 are operated concurrently, causing the metal ions in the plating solution 428 to drift to the first surfaces 416 unobstructed, and to drift to the second surfaces 418 at a slower rate, due to the second screen 438. A flow of the metal ions to the second surfaces 418 may advantageously be more uniform, due to the apertures 444 across the second screen 438, compared to a solid screen. The result is a first average current flowing from the first anode 430 to the first surfaces 416, and a second average current flowing from the second anode 432 to the second surfaces 418. The second average current is 10 percent to 80 percent of the first average current.

The solderable metal 420 is electroplated onto the first surfaces 416 at a first rate and is electroplated onto the second surfaces 418 at a second rate that is lower than the first rate. The lower electroplating rate on the second surfaces 418 produces a lower thickness of the solderable metal 420 on the second surfaces 418, compared to the first surfaces 416, as disclosed in reference to FIG. 1 and FIG. 2. A size and distribution of the apertures 444 of the second screen 438 may be adjusted to attain a desired electroplating rate of the solderable metal 420 on the second surfaces 418, advantageously enabling use of the second power supply 442 in a constant voltage mode at a same voltage as the first power supply 440.

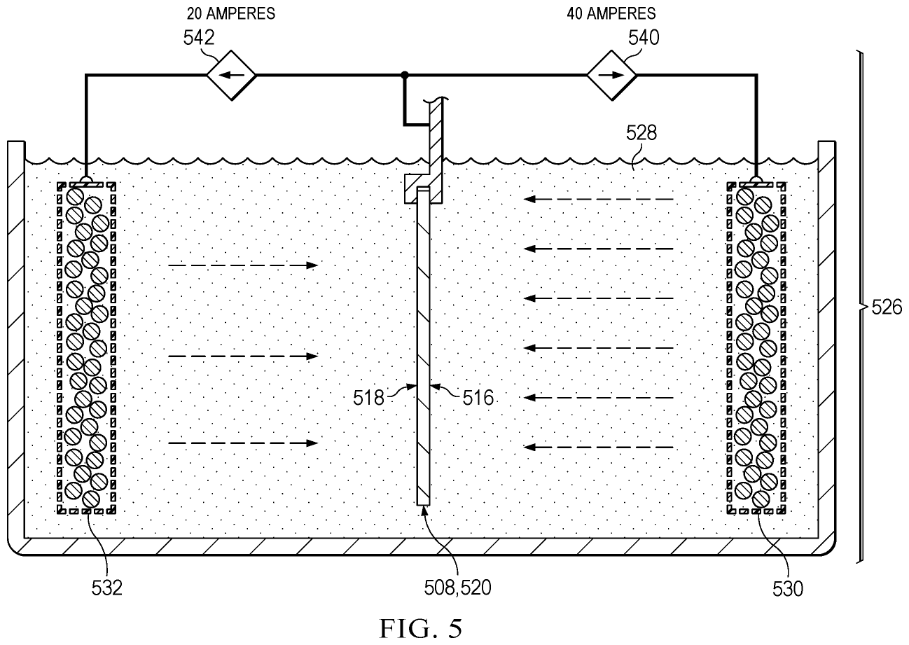

FIG. 5 depicts a further example method of forming a semiconductor package having a second average thickness of a solderable metal on second surfaces of leads that is less than a first average thickness of the solderable metal on first surfaces of the leads. A lead frame 508 for the semiconductor package has first surfaces 516 on one face of the lead frame 508 and has second surfaces 518 on an opposite face from the first surfaces 516. The lead frame 508 is immersed in a plating system 526. The plating system 526 includes a plating solution 528 having metal ions of a solderable metal 520 being electroplated onto the lead frame 508. The plating system 526 also includes a first anode 530 facing the first surfaces 516, and includes a second anode 532 facing the second surfaces 518.

In this example, the plating system 526 includes a first power supply 540 configured to supply a constant first average current from the lead frame 508 to the first anode 530, and a second power supply 542 configured to supply a constant second average current from the lead frame 508 to the second anode 532. The second average current is 10 percent to 80 percent of the first average current. The first power supply 540 and the second power supply 542 of this example are implemented as constant current sources, as indicated schematically in FIG. 5. By way of example, the first power supply 540 may be configured to provide 40 amperes, and the second power supply 542 configured to provide 20 amperes, as indicated in FIG. 5.

During an electroplating process using the plating system 526, the first power supply 540 and the second power supply 542 are operated concurrently, causing the metal ions in the plating solution 528 to drift to the first surfaces 516 unobstructed, and to drift to the second surfaces 518 at a slower rate, due to the second average current being less than the first average current. The solderable metal 520 is electroplated onto the first surfaces 516 at a first rate and is electroplated onto the second surfaces 518 at a second rate that is lower than the first rate. The lower electroplating rate on the second surfaces 518 produces the lower thickness of the solderable metal 520 on the second surfaces 518, compared to the first surfaces 516, as disclosed in reference to FIG. 1 and FIG. 2. The second average current from the second power supply 542 may be adjusted to provide a desired thickness of the solderable metal 520 on the second surfaces 518. Using the first power supply 540 and the second power supply 542 in constant current modes may advantageously enable the plating system 526 to form the solderable metal 520 with desired thicknesses on the first surfaces 516 and the second surfaces 518 without use of screens in the plating solution 528.

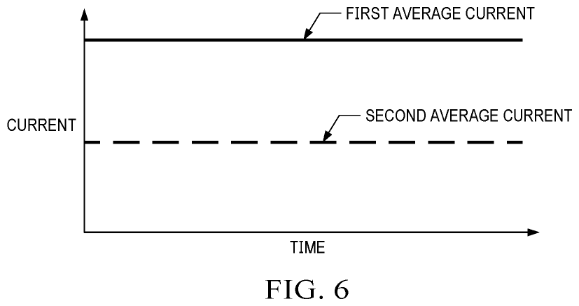

FIG. 6 is a chart of current as a function of time for the plating system disclosed in reference to FIG. 5. The first average current, labeled “FIRST AVERAGE CURRENT” in FIG. 6, is constant during the electroplating operation. Similarly, the second average current, labeled “SECOND AVERAGE CURRENT” in FIG. 6, is also constant during the electroplating operation. During the electroplating operation, the first average current and the second average current are provided concurrently, and may be provided for identical lengths of time, advantageously reducing a cycle time for the electroplating operation compared to providing the currents for different, overlapping, lengths of time.

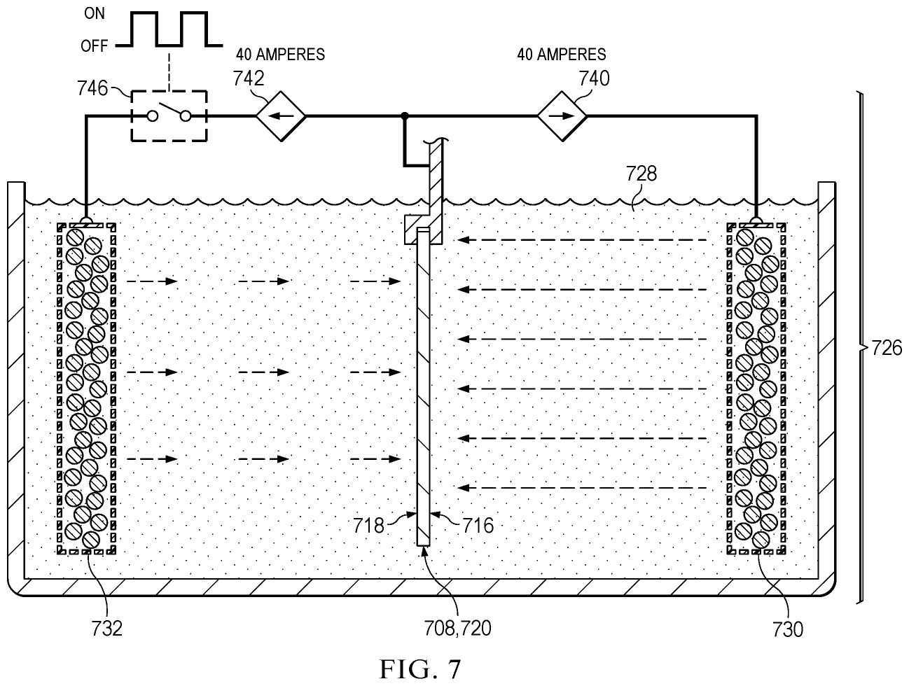

FIG. 7 depicts another example method of forming a semiconductor package having a second average thickness of a solderable metal on second surfaces of leads that is less than a first average thickness of the solderable metal on first surfaces of the leads. A lead frame 708 for the semiconductor package has first surfaces 716 on one face of the lead frame 708 and has second surfaces 718 on an opposite face from the first surfaces 716. The lead frame 708 is immersed in a plating system 726. The plating system 726 includes a plating solution 728 having metal ions of a solderable metal 720 being electroplated onto the lead frame 708. The plating system 726 also includes a first anode 730 facing the first surfaces 716, and includes a second anode 732 facing the second surfaces 718.

The plating system 726 includes a first power supply 740 configured to supply a constant first average current from the lead frame 708 to the first anode 730. In this example, the plating system 726 includes a second power supply 742 configured to supply a second current, modulated by a switch 746, from the lead frame 708 to the second anode 732. The switch 746 may be implemented as a solid state relay, by way of example. The switch 746 is configured to be modulated between an ON state and an OFF state. The second current alternates between essentially zero, when the switch 746 is in the OFF state, and a current magnitude comparable to the first average current, when the switch 746 is in the ON state. An average of the second current, that is, the second average current, is 10 percent to 80 percent of the first average current. A duty cycle of the switch 746, that is a ratio of a total time in the ON state to a sum of the total time in the ON state and a total time in the OFF state, may be adjusted to provide a desired value for the second average current. The first power supply 740 and the second power supply 742 of this example are implemented as constant current sources, as indicated schematically in FIG. 7. By way of example, the first power supply 740 may be configured to provide 40 amperes, and the second power supply 742 configured to provide 40 amperes, as indicated in FIG. 7.

During an electroplating process using the plating system 726, the first power supply 740 and the second power supply 742, modulated by the switch 746, are operated concurrently, causing the metal ions in the plating solution 728 to drift to the first surfaces 716 unobstructed, and to drift to the second surfaces 718 at a slower rate, due to the second average current being less than the first average current. The solderable metal 720 is electroplated onto the first surfaces 716 at a first rate and is electroplated onto the second surfaces 718 at a second rate that is lower than the first rate. The lower electroplating rate on the second surfaces 718 produces the lower thickness of the solderable metal 720 on the second surfaces 718, compared to the first surfaces 716, as disclosed in reference to FIG. 1 and FIG. 2. The second average current from the second power supply 742 may be adjusted to provide a desired thickness of the solderable metal 720 on the second surfaces 718. Use of the switch 746 to modulate the second current may advantageously facilitate adjusting the second average current to the desired value without a need to adjust the second power supply 742.

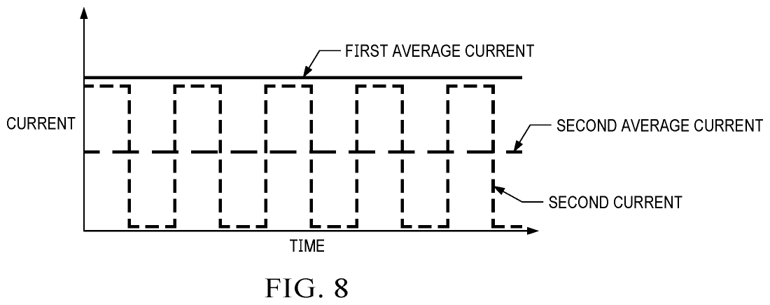

FIG. 8 is a chart of current as a function of time for the plating system disclosed in reference to FIG. 7. The first average current, labeled “FIRST AVERAGE CURRENT” in FIG. 8, is constant during the electroplating operation. The second current, labeled “SECOND CURRENT” in FIG. 8, alternates between essentially zero and a value supplied by the first power supply 740 of FIG. 7 when the switch 746 is in the ON state, during the electroplating operation. The second average current, labeled “SECOND AVERAGE CURRENT” in FIG. 8, is 10 percent to 80 percent of the first average current.

Various features of the examples disclosed herein may be combined in other manifestations of example semiconductor packages. For example, any of the methods disclosed in reference to FIG. 3A, FIG. 4A, FIG. 5, and FIG. 7 may be used to form an SOIC or SOT semiconductor package, as disclosed in reference to FIG. 1. Any of the methods disclosed in reference to FIG. 3A, FIG. 4A, FIG. 5, and FIG. 7 may be used to form a j-lead semiconductor package, as disclosed in reference to FIG. 2. The method disclosed in reference to FIG. 3A may implement the first power supply 340 and the second power supply 342 as constant current sources, instead of the constant voltage sources depicted in FIG. 3A. The method disclosed in reference to FIG. 3A may implement the second power supply 342 modulated by a switch, as disclosed in reference to the second power supply 742 modulated by the switch 746 in reference to FIG. 7. The method disclosed in reference to FIG. 4A may implement the first power supply 440 and the second power supply 442 as constant current sources, instead of the constant voltage sources depicted in FIG. 4A. The method disclosed in reference to FIG. 4A may implement the second power supply 442 modulated by a switch, as disclosed in reference to the second power supply 742 modulated by the switch 746 in reference to FIG. 7. The method disclosed in reference to FIG. 5 may implement the first power supply 540 and the second power supply 542 as constant voltage sources, instead of the constant current sources depicted in FIG. 5. The method disclosed in reference to FIG. 5 may implement the second power supply 542 modulated by a switch, as disclosed in reference to the second power supply 742 modulated by the switch 746 in reference to FIG. 7. The method disclosed in reference to FIG. 5 may implement a solid screen between the second anode 532 and the second surfaces 518, as disclosed in reference to the second screen 338 of FIG. 3A. The method disclosed in reference to FIG. 5 may implement a perforated screen between the second anode 532 and the second surfaces 518, as disclosed in reference to the second screen 438 of FIG. 4A and FIG. 4B. The method disclosed in reference to FIG. 7 may implement the first power supply 740 and the second power supply 742 as constant voltage sources, instead of the constant current sources depicted in FIG. 7. The method disclosed in reference to FIG. 7 may implement a solid screen between the second anode 732 and the second surfaces 718, as disclosed in reference to the second screen 338 of FIG. 3A. The method disclosed in reference to FIG. 7 may implement a perforated screen between the second anode 732 and the second surfaces 718, as disclosed in reference to the second screen 438 of FIG. 4A and FIG. 4B.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A semiconductor package, comprising:
a semiconductor component;
a plurality of leads electrically connected to the semiconductor component;
an encapsulation material contacting the semiconductor component and the leads, wherein the leads extend through the encapsulation material to an exterior of the semiconductor package, each of the leads having a first surface and a second surface opposite from the first surface; and
a solderable metal on the leads, the solderable metal having a first average thickness on the first surfaces and having a second average thickness on the second surfaces, wherein the second average thickness is 10 percent to 80 percent of the first average thickness.

2. The semiconductor package of claim 1, wherein the solderable metal primarily includes a metal selected from the group consisting of tin, silver, nickel, gold, palladium, and an alloy thereof.

3. The semiconductor package of claim 1, wherein the solderable metal primarily includes tin.

4. The semiconductor package of claim 1, wherein the first average thickness of the solderable metal is 5 microns to 20 microns.

5. The semiconductor package of claim 1, wherein the leads have a gull wing configuration.

6. The semiconductor package of claim 1, wherein the leads have a j-lead configuration.

7. The semiconductor package of claim 1, wherein the solderable metal exposes a portion of the leads adjacent to the semiconductor component.

8. A method of forming a semiconductor package, comprising:
concurrently electroplating a solderable metal on a lead frame having a plurality of leads, each of the leads having a first surface and a second surface opposite from the first surface, wherein:
the solderable metal is electroplated on the first surfaces with a first average plating current, and the solderable metal is electroplated on the second surfaces with a second average plating current that is 10 percent to 80 percent of the first average plating current.

9. The method of claim 8, wherein electroplating the solderable metal is performed using a solid screen located between an anode and the lead frame, with the second surfaces facing the solid screen.

10. The method of claim 9, wherein the solid screen extends past a center of the lead frame.

11. The method of claim 8, wherein electroplating the solderable metal is performed using a perforated screen located between an anode and the lead frame, with the second surfaces facing the perforated screen.

12. The method of claim 11, wherein the perforated screen extends past a center of the lead frame.

13. The method of claim 8, wherein electroplating the solderable metal is performed using a first constant current through a first anode facing the first surfaces and a second constant current through a second anode facing the second surfaces, the second constant current being 10 percent to 80 percent of the first constant current.

14. The method of claim 8, wherein electroplating the solderable metal is performed using a first current through a first anode facing the first surfaces and a second current through a second anode facing the second surfaces, the second current being modulated by a switch.

15. The method of claim 14, wherein an average of the second current is 10 percent to 80 percent of an average of the first current.

16. The method of claim 8, wherein the solderable metal primarily includes a metal selected from the group consisting of tin, silver, nickel, gold, and palladium.

17. The method of claim 8, wherein the solderable metal primarily includes tin.

18. The method of claim 8, wherein the solderable metal is electroplated to a first average thickness on the first surfaces and is electroplated to a second average thickness on the second surfaces, the second average thickness being 10 percent to 80 percent of the first average thickness.

19. The method of claim 18, wherein the first average thickness is 5 microns to 20 microns.

20. The method of claim 8, wherein the solderable metal exposes a portion of the leads adjacent to a semiconductor component of the semiconductor package.
